(19) United States
(12) Patent Application Publication
(10) Pub. No.: US 2006/0172484 A1
(43) Pub. Date: Aug. 3, 2006

(54) Method of forming a thin layer and method of manufacturing a flash memory device and a capacitor using the same

(75) Inventors: Suk-Jin Chung, Suwon-si (KR); Jung-Hee Chung, Seoul (KR); Jong-Cheol Lee, Seoul (KR); Jin-Yong Kim, Seoul (KR); Kwang-Hee Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/341,553

(22) Filed: Jan. 30, 2006

(30) Foreign Application Priority Data
Jan. 31, 2005 (KR) 2005-0008625

(51) Int. Cl. H01L 21/8242

(52) U.S. Cl. 438/239

(57) ABSTRACT

In a method of forming a thin layer and a method of manufacturing a flash memory and a capacitor using the same, a first thin layer may be formed on a substrate, and the thin layer may include one of metal, metal nitride and a combination thereof. A binding inhibitor may be formed on the first thin layer by a surface treatment on the first thin layer. The binding inhibitor may reduce a bonding strength between first and second elements when a second thin layer is formed on the first thin layer in a subsequent process using a precursor including the first element and the second element having a ligand binding to the first element. In a flash memory, the first and second thin layers may be a floating gate and a dielectric layer, respectively, and in a capacitor, the first and second thin layers may be a lower electrode and a dielectric layer, respectively.

### PRIORITY STATEMENT

This application claims priority form Korean Patent Application No. 2005-8625 filed on Jan. 31, 2005, the content of which is herein incorporated by reference in its entirety.

### BACKGROUND OF THE INVENTION

1. Field of the Invention

Example embodiments of the present invention relate to a method of forming a thin layer and a method of manufacturing a flash memory device and a capacitor using the same. More particularly, example embodiments of the present invention relate to a method of forming a thin layer including metal oxide on metal or metal nitride and a method of manufacturing a flash memory device and a capacitor for a semiconductor device using the same.

2. Description of the Related Art

A dielectric thin layer for a semiconductor device such as a flash memory device and a capacitor may include a material having a high dielectric constant that is known as a high-k material. The thin layer including the high-k material (hereinafter, referred to as high-k thin layer) may be advantageous in that the current leakage between a floating gate and a control gate of a flash memory or between lower and upper electrodes of a capacitor may be sufficiently reduced despite a sufficiently thin equivalent oxide thickness (EOT) thereof.

Accordingly, a dielectric thin layer, for example, a dielectric layer for a flash memory or a capacitor may be improved by increasing the dielectric constant and reducing EOT, and metal oxide has been used as the dielectric thin layer.

However, a thin layer including metal oxide may not increase dielectric constant and/or reduce EOT sufficiently in newer semiconductor devices.

### SUMMARY OF THE INVENTION

Example embodiments of the present invention provide a method of forming a thin layer having a higher dielectric constant and/or a smaller EOT.

Example embodiments of the present invention also provide a method of manufacturing a flash memory device including a thin layer.

Example embodiments of the present invention also provide a method of manufacturing a capacitor for a semiconductor device including a thin layer.

According to an example embodiment of the present invention, there is provided a method of forming a thin layer having a higher dielectric constant and/or a smaller EOT. A first thin layer may be formed on a substrate, and the thin layer may include one of a metal, metal nitride and a combination thereof. A binding inhibitor may be formed on the first thin layer by a surface treatment on the first thin layer. The binding inhibitor may reduce a bonding strength between first and second elements when a second thin layer is formed on the first thin layer in a subsequent process using a precursor including the first element and the second element having a ligand binding to the first element.

According to another example embodiment of the present invention, there is provided a method of manufacturing a flash memory device. A tunnel oxide layer may be formed on a substrate. A floating gate may be formed on the tunnel oxide layer, and the floating gate may include one of a first metal, a first metal nitride and a first combination thereof. A binding inhibitor may be formed on a surface of the floating gate by a surface treatment on the floating gate. A dielectric layer may be formed on the floating gate including the binding inhibitor by using a precursor including the first and second elements having a ligand binding to the first element. The binding inhibitor may reduce a bonding strength between first and second elements. A control gate may be formed on the dielectric layer, and the control gate may include one of a second metal, a second metal nitride and a second combination thereof.

According to another example embodiment of the present invention, there is provided a method of manufacturing a capacitor for a semiconductor device. A lower electrode may be formed on a substrate. The lower electrode may include a first metal, a first metal nitride or a combination thereof. A binding inhibitor may be formed on a surface of the lower electrode by a surface treatment on the lower electrode. A dielectric layer may be formed on the lower electrode including the binding inhibitor by using a precursor including the first and second elements having a ligand binding to the first element. The binding inhibitor may reduce a bonding strength between first and second elements. An upper electrode may be formed on the dielectric layer, and the upper electrode may include one of a second metal, a second metal nitride and a second combination thereof.

According to another example embodiment of the present invention, there is provided a method of manufacturing a capacitor for a semiconductor device. A lower electrode may be formed on a substrate, and the lower electrode may include a first metal, a first metal nitride or a combination thereof. A binding inhibitor may be formed on a surface of the lower electrode by a surface treatment on the lower electrode. A dielectric layer, which may include a metal oxide, may be formed on the lower electrode including the binding inhibitor by using a precursor including one of an amide group, alkoxide group and halide group. An upper electrode may be formed on the dielectric layer, and the upper electrode may include one of a second metal, a second metal nitride and a second combination thereof.

According to another example embodiment of the present invention, there is provided a method of manufacturing a capacitor for a semiconductor device. An insulation pattern may be formed on a substrate, and the insulation pattern may include an opening through which the substrate is partially exposed. A thin layer may be formed on a surface of the insulation pattern, on a sidewall of the opening and on a surface of the substrate exposed through the opening. The thin layer may include a first sub-layer that includes a first metal or metal-dominated metal nitride and a second sub-layer that includes a first metal nitride. A sacrificial layer may be formed on a resultant structure including the thin layer. The sacrificial layer may be removed until a top surface of the insulation pattern is exposed, so that the sacrificial layer and the thin layer remain in the opening to thereby perform node separation for a lower electrode. The sacrificial layer and the insulation pattern may be removed from the substrate, thereby forming a cylindrical lower electrode. A binding inhibitor, which may include an oxygen-dominated inhibitor and a nitrogen-dominated inhibitor, may be formed on a surface of the lower electrode by an oxidation treatment on the lower electrode. The oxygen-dominated inhibitor may be formed on the first sub-layer of the lower electrode that includes the first metal or metal-dominated metal nitride and the nitrogen-dominated inhibitor may be formed on the second sub-layer of the lower electrode that includes the first metal nitride. A dielectric layer that includes a metal oxide may be formed on the lower electrode, and an upper electrode may be formed on the dielectric layer. The dielectric layer may include one of a second metal, a second metal nitride and a combination thereof.

According to example embodiments of the present invention, an upper thin layer, for example, a dielectric layer for a capacitor or a flash memory may be formed on a lower thin layer on which a surface treatment is performed, so that layer characteristics of the upper thin layer are improved due to the surface treatment

### BRIEF DESCRIPTION OF THE DRAWINGS

The above and other features and advantages of example embodiments of the present invention will become readily apparent by reference to the following detailed description when considering in conjunction with the accompanying drawings, in which:

FIGS. 1A to 1C are cross sectional views illustrating processing operations for a method of forming a thin layer according to an example embodiment of the present invention;

FIGS. 2A to 2D are example cross sectional views illustrating processing operations for a method of manufacturing a flash memory device;

FIGS. 3A to 3C are cross sectional views illustrating processing operations for a method of manufacturing a capacitor according to another example embodiment of the present invention;

FIGS. 4A to 4I are cross sectional views illustrating a method of manufacturing a capacitor according to another example embodiment of the present invention;

FIGS. 5 to 7 are diagrams showing an example distribution of the binding inhibitors after the surface treatment;

FIG. 8 is a graph showing example current leakage of a capacitor experiencing an oxidation treatment as the surface treatment; and

FIG. 9 is an example graph showing a current leakage of a capacitor experiencing a reduction treatment as the surface treatment.

### DESCRIPTION OF EXAMPLE EMBODIMENTS

The invention is described more fully hereinafter with reference, to the accompanying drawings, in which example embodiments of the invention are shown. This invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another clement or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one clement or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, operations, operations, elements, and/or components, but do not preclude the presence or addition of one or more other features, integers, operations, operations, elements, components, and/or groups thereof.

Example embodiments of the invention are described herein with reference to cross-section illustrations that are schematic illustrations of example embodiments (and intermediate structures) of the invention. As such, variations from the shapes of the illustrations as a result, for example, of manufacturing techniques and/or tolerances, are to be expected. Thus, example embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

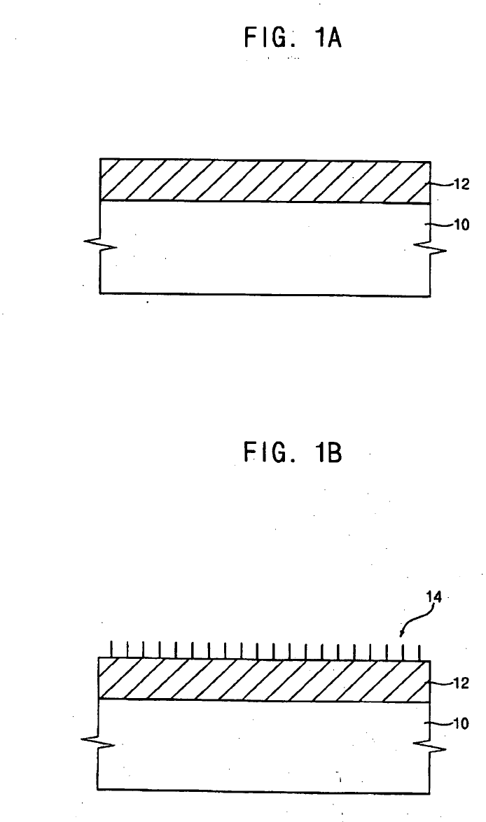

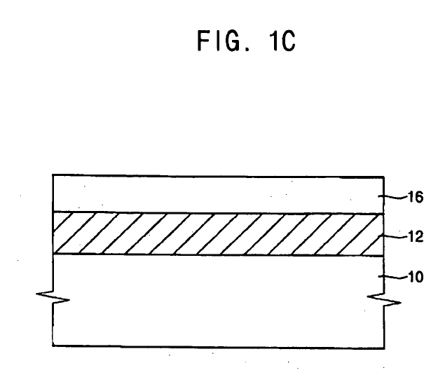

FIGS. 1A to 1C are cross sectional views illustrating processing operations for a method of forming a thin layer according to an example embodiment of the present invention.

Referring to FIG. 1A, a semiconductor substrate 10 such as a silicon wafer may be prepared.

A first thin layer 12 may be formed on the substrate 10, for example, by a chemical vapor deposition (CVD) process. The first thin layer 12 may be a floating gate of a gate structure for a flash memory device or a lower electrode for a capacitor. A metal or metal nitride may be used as the first thin layer 12. A combination of metal and metal nitride may also be used as the first thin layer 12. Examples of metals include titanium, tantalum, tungsten, aluminum, hafnium, zirconium, copper, etc. The above-listed metals may be used alone or in combinations thereof. Examples of metal nitrides include titanium nitride, tantalum nitride, tungsten nitride, aluminum nitride, hafnium nitride, zirconium nitride, copper nitride, etc. The above-listed metal nitrides may also be used alone or in combinations thereof.

Referring to FIG. 1B, a surface treatment may be performed on a surface of the first thin layer 12, thereby forming a binding inhibitor 14 on the surface of the first thin layer 12. When a second thin layer is formed on the first thin layer 12 in a subsequent process using a precursor including a first element and a second element having a ligand binding to the first element, the binding inhibitor 14 may reduce the bonding strength between the first and second elements. In an example of the present embodiment, the first element includes a metal and the second element includes an oxygen based material such as butoxide and isopropoxide and a nitrogen based material such as amide.

The surface treatment may include an oxidation treatment and/or reduction treatment.

An oxidation treatment may include a heat treatment and/or a plasma treatment using materials including oxygen, as well as, oxygen gas.

In an example embodiment, the heat treatment for the oxidation treatment may be performed at a temperature ranging from about 400° C. to about 550° C. In an example embodiment, the heat treatment for the oxidation treatment may be performed at a temperature ranging from about 450° C. to about 500° C. In an example embodiment, the heat treatment for the oxidation treatment may be performed for a time ranging from about 30 seconds to about 500 seconds.

In an example embodiment, the plasma treatment for the oxidation treatment is performed at a temperature of about 250° C. to about 500° C. and/or a power ranging from about 100 watts to about 500 watts. In an example embodiment, the plasma treatment for the oxidation treatment may be performed at a temperature of about 250° C. to about 400° C. for a time of about 30 seconds to about 500 seconds.

The binding inhibitor 14 may be formed on the surface of the first thin layer 12 by the oxidation treatment on the first thin layer 12. As described above, when a second thin layer is formed on the first thin layer 12 in a subsequent process using a precursor including a first element and a second element having a ligand binding to the first element, the binding inhibitor 14 may reduce the bonding strength between the first and second elements. That is, a material layer based on oxygen may be formed on the surface of the first thin layer 12.

The material based on oxygen may sufficiently reduce or prevent the ambient oxygen around the first thin layer 12 from being diffused into the first thin layer 12.

The reduction treatment may also include a heat treatment or a plasma treatment similar to the oxidation treatment. The reduction treatment may be performed using hydrogen (H₂) gas, ammonia (NH₃) gas, a mixture of hydrogen (H₂) and nitrogen (N₂), a mixture of ammonia (NH₃) and nitrogen (N₂) and a mixture of hydrogen (H₂) and ammonia (NH₃). These may be used alone or in combinations thereof.

In an example embodiment, the heat treatment for the reduction treatment may be performed at a temperature ranging from about 300° C. to about 800° C. In an example embodiment, the heat treatment for the reduction treatment may be performed at a temperature ranging from about 350° C. to about 600° C. In an example embodiment, the heat treatment for the reduction treatment may be performed for a time ranging from about 30 seconds to about 500 seconds.

In an example embodiment, the plasma treatment for the reduction treatment may be performed at a temperature of about 20° C. to about 800° C. under a power ranging from about 400 watts to about 2,500 watts. In an example embodiment, the plasma treatment for the reduction treatment may be performed at a temperature of about 100° C. to about 600° C. for a time of about 30 seconds to about 500 seconds.

As a result, a binding inhibitor 14 may be formed on the surface of the first thin layer 12 by the reduction treatment on the first thin layer 12. As described above, when a second thin layer is formed on the first thin layer 12 in a subsequent process using a precursor including a first element and a second element having a ligand binding to the first element, the binding inhibitor 14 may reduce the bonding strength between the first and second elements. That is, a material including hydrogen is arranged on the surface of the first thin layer 12.

In an example embodiment of the present embodiment, the binding inhibitor 14 may be formed on the surface of the first thin layer 12, thus when a second thin layer is formed on the first thin layer 12 in a subsequent process using a precursor including a first element and a second element having a ligand binding to the first element, the binding inhibitor 14 may reduce the bonding strength between the first and second elements.

Referring to FIG. 1C, the second thin layer 16 may be formed on the first thin layer 12 using a precursor including the first and second elements. The second thin layer 16 may be used as a dielectric layer for a gate structure in a flash memory and a dielectric layer in a capacitor.

The precursor may include any one selected among an amide group, an alkoxide group and a halide group.

For example, when an oxidation treatment is performed on the surface of the first thin layer 12 as the surface treatment, the second thin layer may be formed on the first thin layer including the binding inhibitor 14 using a precursor including an amide group.

The second thin layer 16 may include metal oxide. Examples of metal oxides include HfO₂, ZrO₂, Ta₂O₅, Y₂O₃, Nb₂O₅, Al₂O₃, TiO₂, CeO₂, In₂O₃, RuO₂, MgO, SrO, B₂O₃, SiO₂, GeO₂, SnO₂, PbO, PbO₂, Pb₃O₄, V₂O₃, La₂O₃, As₂O₅, As₂O₃, Pr₂O₃, Sb₂O₃, Sb₂O₅, CaO, P₂O₅, etc. These may be used alone or in combinations thereof.

In an example embodiment, the second thin layer 16 may be formed by a CVD process or an atomic layer deposition (ALD) process.

When the second thin layer 16 is formed by a CVD process, a precursor may be supplied onto the first thin layer 12 while being chemically reacted with an oxidizing agent. The precursor reacted with the oxidizing agent may be deposited onto the surface of the first thin layer 12, thereby forming the second thin layer 16 on the first thin layer 12. Examples of oxidizing agents include ozone (O₃), vapor (H₂O), hydrogen peroxide (H₂O₂), methanol (CH₃OH), ethanol (C₂H₅OH), oxygen (O₂) activated by plasma or remote plasma, etc. These can be used alone or in combinations thereof.

When the second thin layer 16 is formed by an ALD process, a precursor may be supplied into an ALD chamber in which the substrate including the first thin layer 12 is loaded. A first element of the precursor may be chemisorbed onto the surface of the first thin layer 12, and a second element of the precursor may be physisorbed onto the surface of the first thin layer 12. A purge gas may be supplied into the ALD chamber, so that the second element of the precursor is removed from the first thin layer 12. An oxidizing agent may be supplied onto the first thin layer 12 and may be chemically reacted with the first element of the precursor that is chemisorbed onto the first thin layer 12, so that a solid material containing the first element and the oxidizing agent is formed on the first thin layer 12. A purge gas may again be supplied onto the first thin layer 12 including the solid material, so that residual oxidizing agents, which are not chemically reacted with the first element of the precursor, are removed from the first thin layer 12. The above processing operations may be repeated, thereby forming a second thin layer 16 including the solid material.

Examples of oxidizing agents include ozone (O₃), vapor (H₂O), hydrogen peroxide (H₂O₂), methanol (CH₃OH), ethanol (C₂H₅OH), oxygen (O₂) activated by plasma or remote plasma, etc. These can be used alone or in combinations thereof. An inactive gas such as argon (Ar) gas and/or helium (He) gas may be used as the purge gas.

The second thin layer 16 may be formed on the first thin layer 12 after completing the surface treatment on the first thin layer 12. As a result, the binding inhibitor 14 on the first thin layer 12 by the surface treatment may reduce the bonding strength between the first and second elements of the precursor when the second thin layer 16 is formed on the first thin layer 12.

For example, when a precursor including a first element and a second element having a ligand binding to the first element is supplied onto the first thin layer 12 on which an oxidation treatment is performed as a surface treatment, oxygen on the first thin layer 12 may be chemically bonded with the first element of the precursor. Oxygen is more strongly bonded with the first element of the precursor than the second element in the precursor, so that the bonding strength of the first and second elements of the precursor is reduced. Accordingly, the first and second elements may be separated from each other in the precursor, thereby forming a second thin layer 16 having improved layer characteristics.

As another example, when a precursor including a first element and a second element having a ligand binding to the first element is supplied onto the first thin layer 12 on which a reduction treatment is performed as a surface treatment, hydrogen on the first thin layer 12 may be chemically bonded with the first element of the precursor. Hydrogen is more strongly bonded with the first element of the precursor than the first and second elements of the precursor are bonded with each other, so that the bonding strength of the first and second elements of the precursor is reduced. Accordingly, the first and second elements may be separated from each other in the precursor, thereby forming a second thin layer 16 having improved layer characteristics.

According to example embodiments of the present embodiment, a surface treatment may be performed on the first thin layer 12, and a binding inhibitor 14 may be formed on the first thin layer 12. When a second thin layer is formed on the first thin layer 12 in a subsequent process using a precursor including a first element and a second element having a ligand binding to the first element, the binding inhibitor 14 may reduce the bonding strength between the first and second elements in the precursor. As a result, the precursor may be dissociated into each element thereof, thereby forming a second thin layer having improved characteristics on the first thin layer.

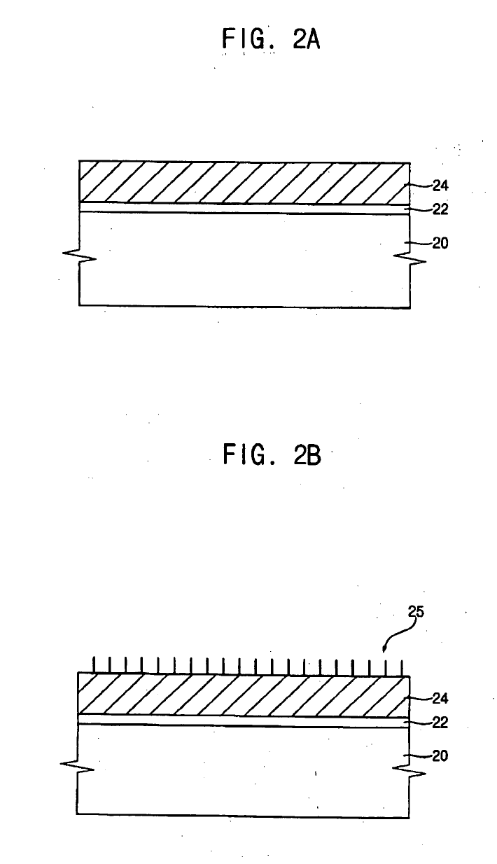

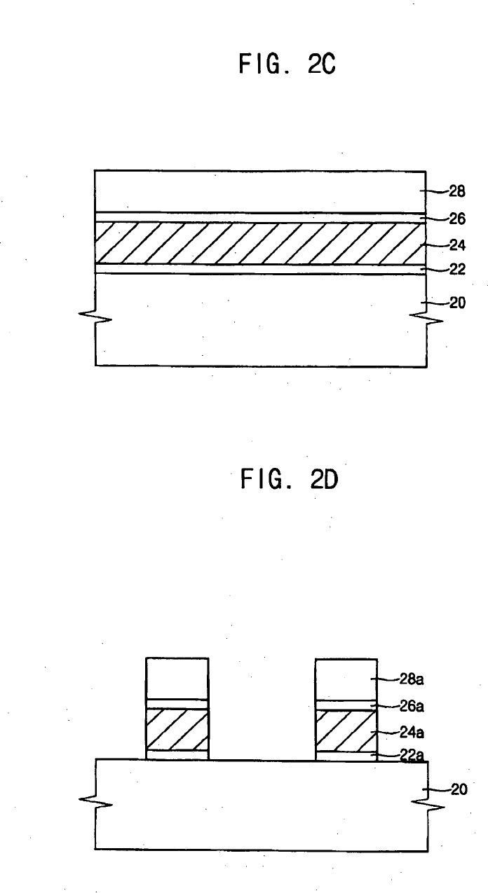

FIGS. 2A to 2D are cross sectional views illustrating processing operations for a method of manufacturing a flash memory device according to an example embodiment of the present invention.

Referring to FIG. 2A, a semiconductor substrate 20 such as a silicon wafer may be provided and a device isolation layer (not shown) such as a trench isolation layer may be formed on the substrate 20. A tunnel oxide layer 22 may be formed on the substrate 20. In an example embodiment, a silicon oxide layer may be formed on the substrate 20 by a thermal oxidation process or a radical oxidation process to a thickness of about 10 Å to about 500 Å as the tunnel oxide layer 22.

A first conductive layer 24 may be formed on the tunnel oxide layer 22 by a CVD process. The first conductive layer 24 may be substantially identical to the first thin layer as discussed above, so that the first conductive layer 24 may include conductive material such as metal or metal nitride. In a subsequent process, the first conductive layer 24 may be formed as a floating gate of a gate structure in a flash memory device.

Referring to FIG. 2B, a surface treatment may be performed on the first conductive layer 24. The surface treatment of an example embodiment may be the same as discussed above, thereby forming a binding inhibitor 25 on the first conductive layer 24. When a preliminary dielectric layer is formed on the first conductive layer 24 in a subsequent process using a precursor including a first element and a second element having a ligand binding to the first element, the binding inhibitor 24 may reduce the bonding strength between the first and second elements.

Referring to FIG. 2C, the preliminary dielectric layer 26 may be formed on the first conductive layer 24 after completing the surface treatment. The preliminary dielectric layer 26 may be formed in the same process as the second thin layer discussed above, and a thickness of the preliminary dielectric layer may range from about 200 Å to about 600 Å. Accordingly, a precursor including an amide group, an alkoxide group or a halide group may be deposited on the first conductive layer 24 by a CVD process or an ALD process, thereby forming the preliminary dielectric layer 26 including metal oxide. The metal oxide may be the same as the metal oxide described above.

In an example embodiment, the preliminary dielectric layer 26 may be formed on the first conductive layer 24 on which the surface treatment is performed, so that an EOT of the preliminary dielectric layer 26 may be reduced and/or current leakage characteristics of the preliminary dielectric layer 26 may be improved. For example, the EOT of the preliminary dielectric layer 26 is smaller than that of a metal oxide layer, thereby increasing a capacitance of a capacitor. Also, when the preliminary dielectric layer 26 is used as a dielectric layer of a gate structure in a flash memory, a coupling ratio of the flash memory device may be improved.

A second conducive layer 28 may be formed on the preliminary layer 26. The second conductive layer 28 may also include metal or metal nitride substantially identical to the first conductive layer 24. The second conductive layer 28 may be used as a control gate of a gate structure in a flash memory device.

Referring to FIG. 2D, the second conductive layer 28, the preliminary dielectric layer 26, the first conductive layer 24 and the tunnel oxide layer 22 are sequentially patterned, thereby forming a control gate 28a, a dielectric layer 26a, a floating gate 24a and a tunnel oxide pattern 22a on the substrate 20.

Accordingly, a gate structure including the tunnel oxide pattern 22a, the floating gate 24a, the dielectric layer 26a and the control gate 28a may be formed on the substrate 20.

According to an example embodiment, the preliminary dielectric layer 26 may be formed on the first conductive layer 24 after a surface treatment is performed on the first conductive layer 24 that is to be floating gate 24a of a gate structure. Accordingly, layer characteristics of the dielectric layer 26a may be improved due to the surface treatment. For example, the dielectric layer 26a may have improved current leakage characteristics despite a smaller EOT, so that the flash memory device including the dielectric layer may have improved electrical characteristics.

While the above example embodiment discloses that a dielectric layer may be applied to a planar type gate structure of a flash memory device, a vertical type gate structure, a fin type gate structure or any other configuration known to one of the ordinary skill in the art may also include the dielectric layer in a flash memory device. In a vertical type gate structure, a control gate and a floating gate may be arranged perpendicularly to each other, and a channel region may protrude from a substrate in the fin type gate structure.

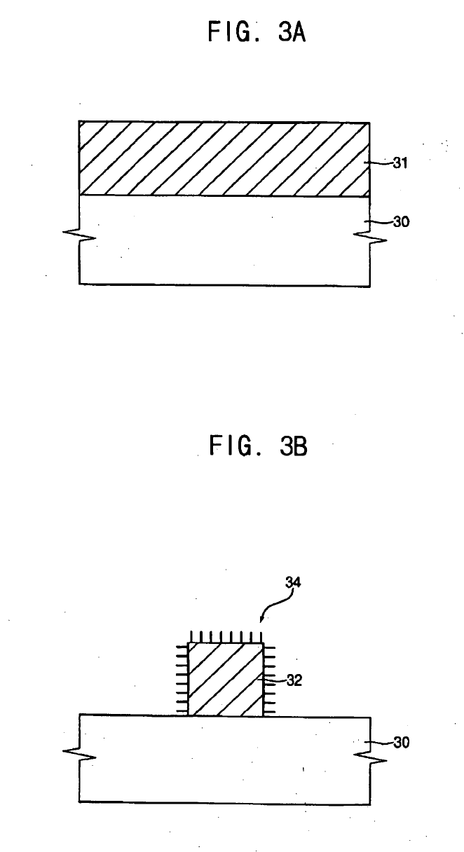

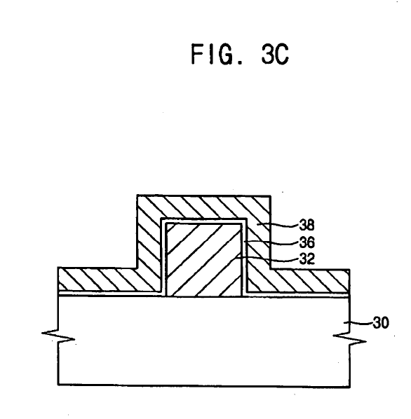

FIGS. 3A to 3C are cross sectional views illustrating processing operations for a method of manufacturing a capacitor according to another example embodiment of the present invention.

Referring to FIG. 3A, a semiconductor substrate 30 such as a silicon wafer may be provided. The substrate 30 is substantially identical to the substrate described above, so that any further detailed description on the substrate 30 is omitted hereafter.

A lower thin layer 31 may be formed on the substrate 30, and the lower thin layer 31 may be formed into a lower electrode of a capacitor. The lower thin layer 31 may have same structure as the first thin layer described above, so that metal or metal nitride may be deposited onto the substrate 30 by a CVD process, to thereby form the lower thin layer 31.

The lower thin layer 31 may be patterned to thereby form a stacked lower electrode 32 on the substrate 30.

Referring to FIG. 3B, a surface treatment may be performed on the lower electrode 32. The surface treatment may be the same described above, thereby forming a binding inhibitor 34 on the lower electrode 32. When a dielectric layer is formed on the lower electrode 32 in a subsequent process using a precursor including a first element and a second element having a ligand binding to the first element, the binding inhibitor 34 may reduce the bonding strength between the first and second elements. In an example of the present embodiment, the first element includes a metal and the second element includes an oxygen based material such as butoxide and isopropoxide and a nitrogen based material such as amide.

Referring to FIG. 3C, a dielectric layer 36 may be formed on the lower electrode 32 after completing the surface treatment. The dielectric layer 36 may be formed with the same process as the second thin layer described above except that a thickness of the dielectric layer may range from about 10 Å to about 150 Å. Accordingly, a precursor including an amide group, an alkoxide group or a halide group may be deposited on the lower electrode 32 by a CVD process or an ALD process, thereby forming the dielectric layer 36, including metal oxide. The metal oxide may be the same as described above.

In an example embodiment, the dielectric layer 36 may be formed on the lower electrode 32 on which the surface treatment is performed, so that an EOT of the dielectric layer 36 may be reduced and/or current leakage characteristics of the dielectric layer 36 may be improved. For example, the EOT of the dielectric layer 36 may be smaller than that of a metal oxide layer, thereby increasing a capacitance of the capacitor.

An upper electrode 38 may be formed on the preliminary layer 36. The upper electrode 38 may have the same structure as the lower electrode 32, so that metal or metal nitride is deposited onto the dielectric layer 36 by a CVD process to there by form the upper electrode 38.

A capacitor including the lower electrode 32, the dielectric layer 36 and the upper electrode 38 may be formed on the substrate 30.

According to an example embodiment, the dielectric layer 36 may be formed on the lower electrode 32 after a surface treatment is performed on the lower electrode 32. Accordingly, layer characteristics of the dielectric layer 36 may be improved due to the surface treatment. That is, the dielectric layer 36 may have improved current leakage characteristics despite a smaller EOT, so that the capacitor has improved electrical characteristics.

Another example embodiment is directed to a method of forming a capacitor, and may be similar to embodiments described above except that an oxidation treatment may be performed on a lower electrode as a surface treatment.

When a dielectric layer is formed on the lower electrode in a subsequent process using a precursor including a first element and a second element having a ligand binding to the first element, a binding inhibitor may be formed on the lower electrode. The binding inhibitor may reduce the bonding strength between the first and second elements and reduce or prevent oxygen from penetrating into the lower electrode. That is, material including oxygen may be arranged on the lower electrode, so that oxygen is abundant on a surface of the lower electrode.

Accordingly, ambient oxygen around the lower electrode is reduced or prevented from being diffused into the lower electrode, thereby improving capacitor characteristics.

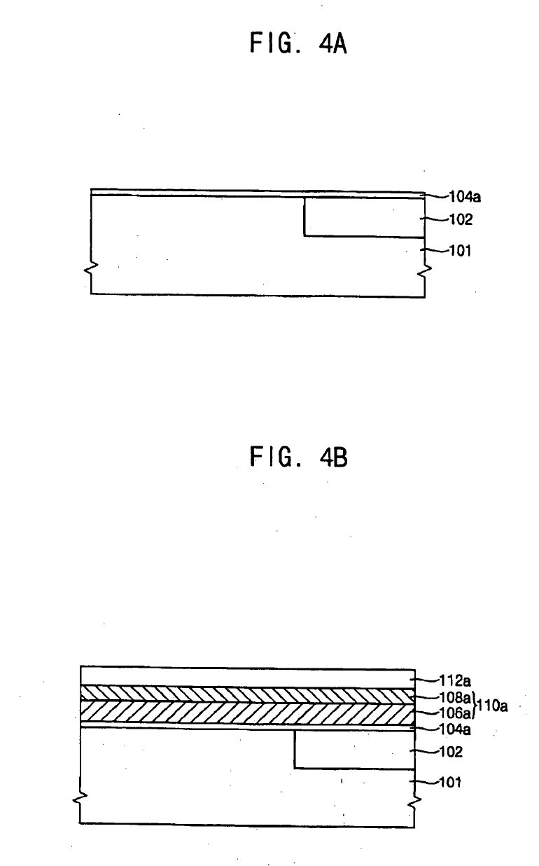

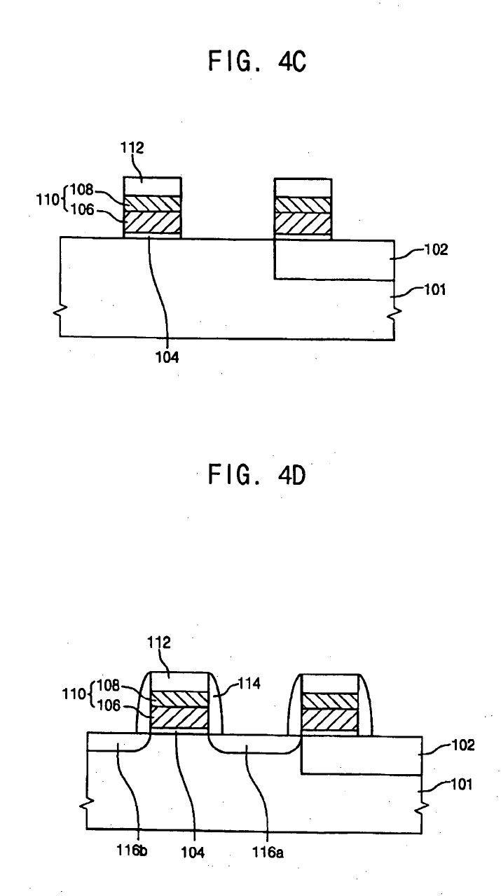

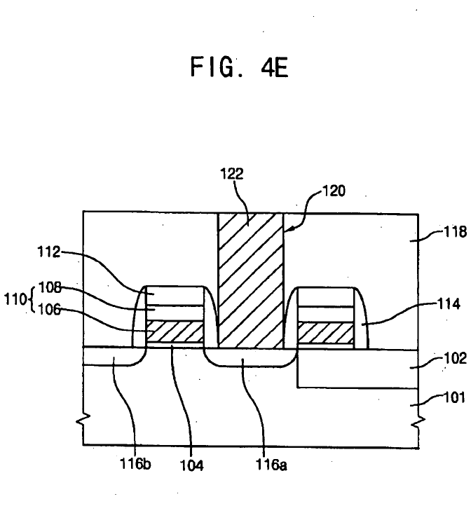

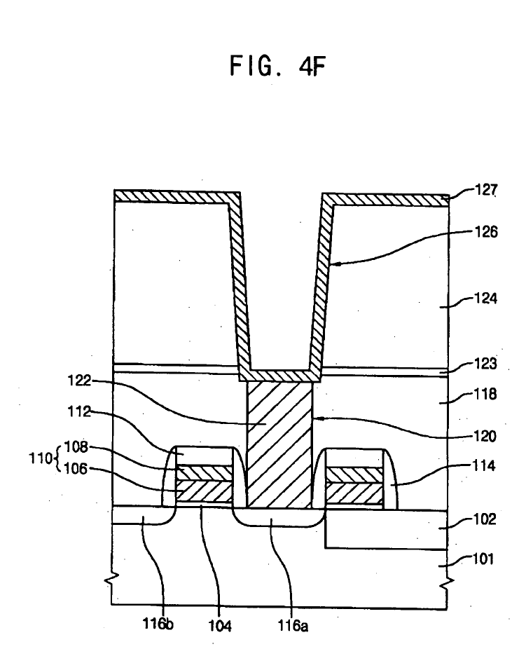

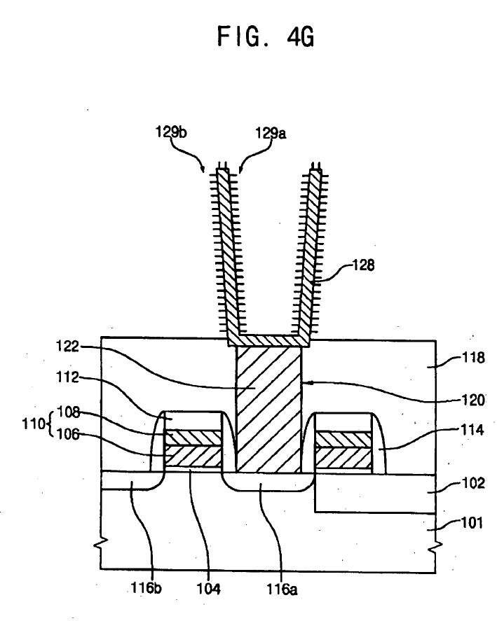

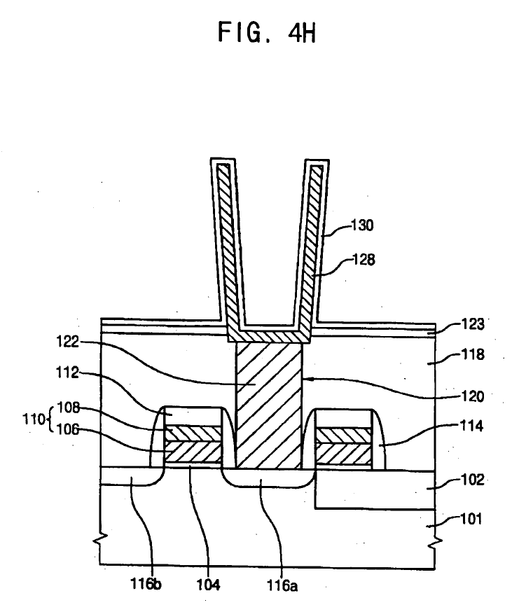

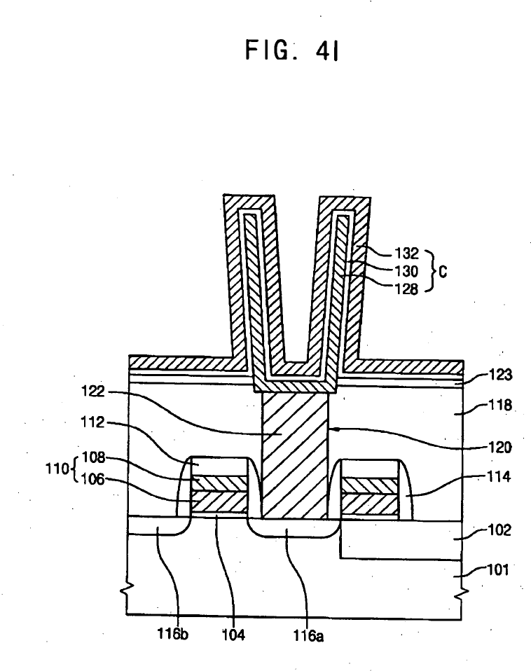

FIGS. 4A to 4I are cross sectional views illustrating a method of manufacturing a capacitor according to another example embodiment of the present invention.

Referring to FIG. 4A, a semiconductor substrate 101 such as a silicon wafer may be provided and a device isolation process is performed on the substrate 101, thereby forming an active region and a field region 102.

A gate insulation layer 104a may be formed on the substrate 101. In an example embodiment, the gate insulation layer 104a may include metal oxide and may be formed to a thickness of about 20 Å to about 100 Å, so that the gate insulation layer 104a reduces or prevents current leakage despite a smaller EOT.

Referring to FIG. 4B, a gate conductive layer 110a may be formed on the gate insulation layer 104a. In an example embodiment, the gate conductive layer 110a may have a double layer structure in which a polysilicon layer and a metal silicide, for example, tungsten silicide are sequentially stacked. A capping insulation layer 112a including silicon may be further formed on the gate conductive layer 110a.

Referring to FIG. 4C, the capping insulation layer 112a, the gate conductive layer 110a and the gate insulation layer 104a may be patterned by a photolithography process, thereby forming agate structure including a capping insulation pattern 112, a gate conductive pattern 110 and a gate insulation pattern 104. For example, the gate conductive pattern 110 may include a polysilicon pattern 106 and a metal silicide pattern 108.

Referring to FIG. 4D, a sidewall spacer 114, which may include silicon nitride, may be formed on a sidewall of the gate structure. Ion implantation may be performed at surface portions of the substrate 101 before and after the sidewall spacer 114, thereby forming source/drain regions 116a and 116b.

Referring to FIG. 4E, a first insulation layer, which may include an oxide, may be formed on the substrate 101 on which the gate structure is formed. The first insulation layer may be patterned by a photolithography process, thereby forming a first insulation pattern 118 including a first contact hole 120 through which the source region is exposed. A conductive layer may be formed on the first insulation pattern 118 to a sufficient thickness to fill the contact hole 120. The conductive layer may be removed and planarized until a top surface of the first insulation pattern 118 is exposed, so that the first conductive layer remains only in the contact hole 120. Accordingly, a contact plug 122 is formed in the contact hole 120. In an example embodiment, the planarization process may be performed by a chemical mechanical polishing (CMP) process or an etching process.

Referring to FIG. 4F, an etching stop layer 123 may be formed on the contact plug 122 and the insulation pattern 118. The etching stop layer 123 may include a material having an etching rate higher than that of the first insulation pattern 118, for example, silicon nitride and/or silicon oxynitride. A second insulation layer, which may include oxide, may be formed on the etching stop layer 123, and may be patterned by a photolithography process, thereby forming a second insulation pattern 124 including a second contact hole 126 through which the contact plug is exposed. For example, the second insulation layer may be removed until a top surface of the etching stop layer 124 is exposed, and the etching stop layer 124 may be removed from the contact plug 122. The second contact hole 126 may be formed at a vertical gradient, so that a size of a lower portion is smaller than that of an upper portion because an etching rate of the second insulation layer gradually decreases as the etching process advances. That is, the upper portion of the second insulation layer may be etched away more than the lower portion of the second insulation layer in the photolithography process.

A thin layer 127 for a lower electrode may be continuously formed on the surface of the second insulation pattern 124, on sidewalls of the second contact hole 126 and a top surface of the contact plug exposed through the second contact hole 126. The thin layer 128 may be formed into a lower electrode for a capacitor in a subsequent process, and may include the same material as the first thin layer described above such as metal or metal nitride.

In an example embodiment, the thin layer 127 may include a first sub-layer including a first metal or a metal-dominated metal nitride in which metal is abundant and a second sub-layer including a first metal nitride. In an example embodiment, the first sub-layer may be continuously formed on the surface of the second insulation pattern 124, on sidewalls of the second contact hole 126 and on the top surface of the contact plug exposed through the second contact hole 126, and the second sub-layer may be formed on the first sub-layer, thereby forming the thin layer 127.

A sacrificial layer (not shown) may be formed on the thin layer 127 to a sufficient thickness to fill the second contact hole 126 and may be removed and planarized until a top surface of the thin layer 127 is exposed, so that the sacrificial layer remains in the second contact hole 126. The thin layer 127 may be removed from the second insulation pattern 124, so that the thin layer remains on sidewall and the top surface of the contact plug exposed through the second contact hole 126. The sacrificial layer may be completely removed from the second contact hole 126, and the thin layer 127 may be separated by a cell unit, which is known as a node separation. Accordingly, a lower electrode 128 may be formed at each cell unit. For example, the lower electrode 128 may be formed to have a cylindrical shape of which a height is about 10,000 Å to about 17,000 Å and of which a size of an upper portion is larger than that of a lower portion.

Referring to FIG. 4G, a surface treatment may be performed on a surface of the lower electrode 128; the surface treatment may be the same as described above. Accordingly, when a dielectric layer is formed on the lower electrode in a subsequent process using a precursor including a first element and a second element having a ligand binding to the first element, a binding inhibitor including an oxygen-dominated inhibitor 129a and a nitrogen-dominated inhibitor 129b may be formed on the lower electrode. The binding inhibitor may reduce the bonding strength between the first and second elements. In an example of the present embodiment, the first element includes a metal and the second element includes an oxygen based material such as butoxide and isopropoxide and a nitrogen based material such as amide.

For example, an oxidation treatment may be performed on the lower electrode 128 as the surface treatment. As a result, the oxygen-dominated inhibitor in which oxygen is abundant may be formed on a first portion of the lower electrode 128 and the nitrogen-dominated inhibitor in which nitrogen is abundant may be formed on a second portion of the lower electrode 128. The first portion of the lower electrode 128 may correspond to the first sub-layer of the thin layer 127, so that the first metal or the metal-dominated metal nitride is included into the first portion of the lower electrode. The second portion of the lower electrode 128 may correspond to the second sub-layer of the thin layer 127, so that the first metal nitride in which nitrogen is relatively abundant is included into the second portion of the lower electrode. For example, the lower electrode 128 may be formed into a cylindrical shape, so the first portion is formed into an outer sidewall of the cylindrical lower electrode 128 and the second portion is formed into an inner sidewall of the cylindrical lower electrode 128.

Referring to FIG. 4H, a dielectric layer 130 may be formed on the lower electrode 128 on which the surface treatment is performed. The dielectric layer 130 may be formed by the same process described above for forming the second thin layer. Accordingly, a precursor including an amide group, an alkoxide group or a halide group may be deposited on the lower electrode 128 by a CVD process or an ALD process, so the dielectric layer 130 including metal oxide is formed on the lower electrode 128. The metal oxide may be the same as described above. In an example embodiment, the dielectric layer 130 may be formed on the lower electrode 128 on which the surface treatment is performed, so an EOT of the dielectric layer 130 is reduced and/or current leakage characteristics of the dielectric layer 130 may be improved.

For example, the EOT of the dielectric layer 130 may be smaller than that of a metal oxide layer, so a capacitance of the capacitor including the dielectric layer 130 may increase.

Referring to FIG. 41, a heat treatment may be performed on the dielectric layer 130, so impurities in or on the dielectric layer 130 may be removed from the dielectric layer 130 and oxygen deficiencies in or on the dielectric layer 130 may be sufficiently cured. The heat treatment may include an ultra violet ray and ozone (O₃) treatment, a plasma treatment, etc.

An upper electrode 132 may be formed on the dielectric layer 130. The upper electrode 132 may have the same structure as the lower electrode 128, so that a second metal or a second metal nitride may be deposited onto the dielectric layer 130 by a CVD process so as to form the upper electrode 132.

Accordingly, a capacitor including the lower electrode 128, the dielectric layer 130 and the upper electrode 132 may be formed on the substrate 101.

According to an example embodiment, the dielectric layer 130 may be formed on the lower electrode 128 after a surface treatment is performed on the lower electrode 128. Accordingly, layer characteristics of the dielectric layer 130 may be sufficiently improved due to the surface treatment. That is, the dielectric layer 130 may have improved current leakage characteristics despite a small EOT, so the capacitor has improved electrical characteristics.

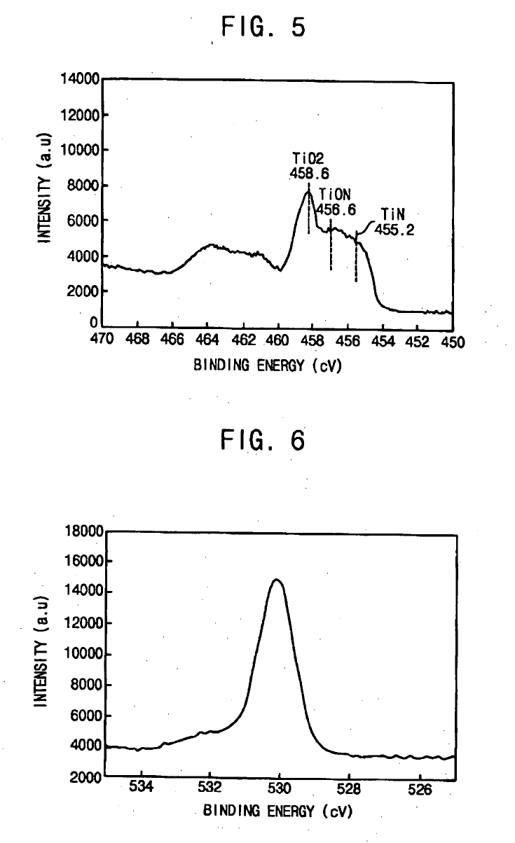

FIGS. 5 to 7 are diagrams showing a distribution of the binding inhibitors after the surface treatment.

A titanium nitride layer was formed on a substrate and an oxygen treatment was performed on a surface of the titanium nitride layer at a temperature of about 500° C. for about 60 seconds. The binding inhibitors on the titanium nitride layer were then analyzed after completing the oxygen treatment.

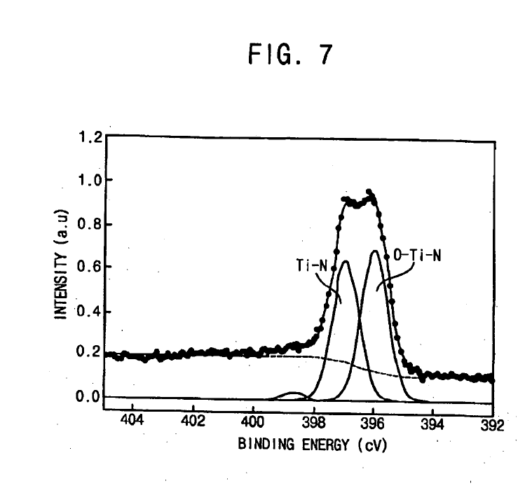

As shown in FIG. 5, titanium oxide and titanium oxynitride were also found at a 2p orbital of titanium as well as titanium nitride, and titanium oxide was found at a 1s orbital of oxygen as shown in FIG. 6. Further, titanium nitride was also found at a 1s orbital of nitrogen as well as titanium oxynitride as shown in FIG. 7.

The above experiments indicate that binding inhibitors are formed on a surface of the thin layer including metal or metal nitride due to the surface treatment on the thin layer. When another layer is formed on the thin layer in a subsequent process using a precursor including a first element and a second element having a ligand binding to the first element, the binding inhibitor reduces the bonding strength between the first and second elements.

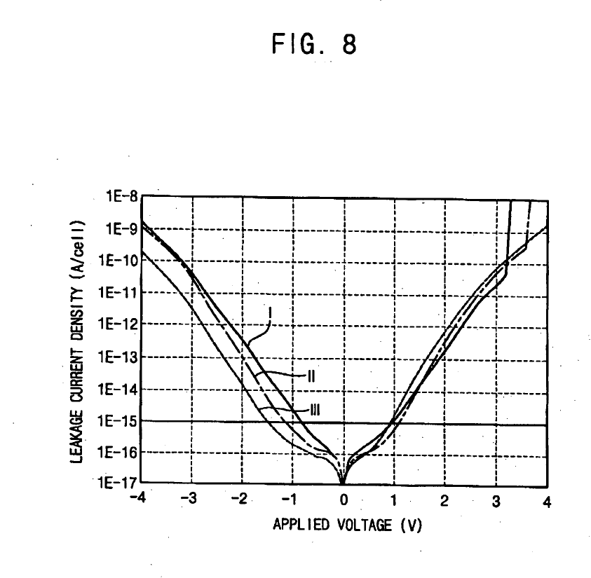

FIG. 8 is a graph showing a current leakage of a capacitor subject to an oxidation treatment as the surface treatment. In FIG. 8, a horizontal line indicates an applied voltage (V) and a vertical line indicates a leakage current density (A/cell).

A first sample capacitor I was prepared to include a lower electrode comprising titanium nitride, a dielectric layer including hafnium oxide and an upper electrode comprising ruthenium. The first sample capacitor I was not subject to the oxidation process, and the dielectric layer was formed on the lower electrode after a cleaning process using hydrogen fluoride gas. An EOT of the dielectric layer of the first sample capacitor I was about 13.8 Å.

A second sample capacitor II was formed by the same process as the first sample capacitor I except that the dielectric layer was formed on the lower electrode after a plasma treatment using oxygen gas in place of the cleaning process using hydrogen fluoride gas. An EOT of the dielectric layer of the second sample capacitor II was about 16.4 Å.

A third sample capacitor III was formed by the same process as the first sample capacitor I except that the dielectric layer was formed on the lower electrode after a heat treatment at a temperature of about 500° C. for about 60 seconds in place of the cleaning process using hydrogen fluoride gas. An EOT of the dielectric layer of the third sample capacitor III was about 12.8 Å.

Referring to FIG. 8, the current leakage characteristics of the second and third sample capacitor II and III were more stable than that of the first sample capacitor I.

Accordingly, the graph in FIG. 8 indicates that the oxidation treatment improves the current leakage characteristics of the capacitor despite a small EOT of the dielectric layer. The capacitor including the dielectric layer subject to the oxidation treatment has improved electrical characteristics.

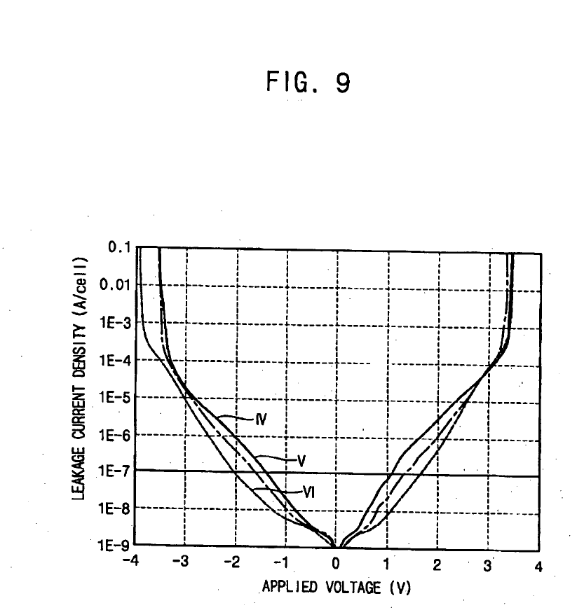

FIG. 9 is a graph showing a current leakage of a capacitor subject to a reduction treatment as the surface treatment. In FIG. 9, a horizontal line indicates an applied voltage (V) and a vertical line indicates a leakage current density (A/cell).

A fourth sample capacitor IV was prepared to include a lower electrode including titanium nitride, a dielectric layer including hafnium oxide and an upper electrode including titanium nitride and tungsten. The reduction process was not performed on the fourth sample capacitor IV, and the dielectric layer was formed on the lower electrode after a cleaning process using hydrogen fluoride gas. An EOT of the dielectric layer of the fourth sample capacitor IV was about 13.56 Å.

A fifth sample capacitor V was formed by the same process as the fourth sample capacitor IV except that the dielectric layer was formed on the lower electrode after a plasma treatment using ammonia (NH3) gas in place of the cleaning process using hydrogen fluoride gas. An EOT of the dielectric layer of the fifth sample capacitor V was about 12.32 Å.

A sixth sample capacitor VI was formed by the same process as the fourth sample capacitor IV except that the dielectric layer was formed on the lower electrode after a plasma treatment using hydrogen (H₂) gas in place of the cleaning process using hydrogen fluoride gas. An EOT of the dielectric layer of the sixth sample capacitor VI was about 12.87 Å.

Referring to FIG. 9, the current leakage characteristics of the fifth and sixth sample capacitor V and VI were more stable than that of the fourth sample capacitor VI.

Accordingly, the graph in FIG. 9 indicates that the reduction treatment improves the current leakage characteristics of the capacitor despite a sufficiently small EOT of the dielectric layer. The capacitor including the dielectric layer on which the reduction treatment is performed has improved electrical characteristics.

TABLE 1

| | | Thickness of | EOT |
|---|---|---|---|
| | Surface treatment | dielectric layer (Å) | (Å) |
| 11^{th} sample | Cleaning process using | 40.7 | 16.2 |
| capacitor | hydrogen fluoride gas | | |
| 12^{th} sample | Heat treatment using oxygen | 43.1 | 15.3 |
| capacitor | gas for about 60 sec. | | |
| 13^{th} sample | Cleaning process using | 40.7 | 16 |
| capacitor | hydrogen fluoride gas | | |
| 14^{th} sample | Heat treatment using oxygen | 45 | 14.6 |
| capacitor | gas for about 60 sec. | | |
| 15^{th} sample | Cleaning process using | 38.6 | 16 |
| capacitor | hydrogen fluoride gas | | |
| 16^{th} sample | Heat treatment using oxygen | 40 | 15.4 |
| capacitor | gas for about 30 sec | | |
| 17^{th} sample | Heat treatment using oxygen | 42.2 | 14.6 |
| capacitor | gas for about 60 sec | | |
| 18^{th} sample | Heat treatment using oxygen | 47.6 | 13 |
| capacitor | gas for about 180 sec | | |
| 19^{th} sample | Cleaning process using | 53.5 | 11.3 |
| capacitor | hydrogen fluoride gas | | |
| 20^{th} sample | Heat treatment using oxygen | 87.7 | 10.4 |
| capacitor | gas for about 60 sec | | |
| 21^{th} sample | Cleaning process using | 43.6 | 13.8 |
| capacitor | hydrogen fluoride gas | | |
| 22^{th} sample | Heat treatment using oxygen | 48.1 | 12.5 |
| capacitor | gas for about 60 sec | | |
| 23^{th} sample | Cleaning process using | 37.6 | 16 |
| capacitor | hydrogen fluoride gas | | |
| 24^{th} sample | Heat treatment using oxygen | 40.8 | 14.8 |
| capacitor | gas for about 60 sec | | |
| 25^{th} sample | Cleaning process using | 34.3 | 17 |
| capacitor | hydrogen fluoride gas | | |
| 26^{th} sample | Heat treatment using oxygen | 43.1 | 13.6 |
| capacitor | gas for about 180 sec | | |
| 27^{th} sample | Heat treatment using oxygen | 45.8 | 12.8 |
| capacitor | gas for about 300 sec | | |

In Table 1, the 11th sample capacitor through the 27th sample capacitor have the same structure except a surface treatment and a thickness of the dielectric layer. In Table 1, all the sample capacitors have a lower electrode including titanium, a dielectric layer including hafnium oxide and aluminum oxide and an upper electrode including titanium nitride.

Table 1 indicates that the heat treatment using oxygen gas among the surface treatments may most efficiently reduce the EOT of the dielectric layer in the capacitor.

Accordingly, the surface treatment of example embodiments of the present invention may reduce the EOT of the dielectric layer, so the capacitor including the dielectric layer has improved capacitance. For example, when the dielectric layer includes a metal oxide, the dielectric layer may have a higher dielectric constant with a sufficiently small EOT, thereby increasing capacitance of the capacitor.

According to example embodiments of the present invention, surface treatments such as an oxidation treatment and a reduction treatment on a thin layer may reduce the EOT of the thin layer with improved current leakage characteristics, so a flash memory device having undergone the surface treatment may have a higher coupling ratio and the capacitor on which the surface treatment is performed may have a higher capacitance.

Although example embodiments of the present invention have been described, it is understood that the present invention should not be limited to these example embodiments but various changes and modifications can be made by one skilled in the art within the spirit and scope of the present invention as hereinafter claimed. For example, although example embodiments of the present invention have described oxidation and reduction as example reactions, other reactions are also candidates. Also, although example embodiments of the present invention have described reducing the bonding strength between first element and second elements, interaction between more than two elements is also contemplated.

What is claimed is:

1. A method of forming a thin layer, comprising:
forming a first thin layer on a substrate, the thin layer including a metal, a metal nitride or a combination thereof; and
forming a binding inhibitor on the first thin layer by a surface treatment on the first thin layer, the binding inhibitor reducing a bonding strength between first and second elements when a second thin layer is formed on the first thin layer in a subsequent process using a precursor including the first element and the second element having a ligand binding to the first element.

2. The method of claim 1, wherein the metal includes at least one selected from the group consisting of titanium, tantalum, tungsten, aluminum, hafnium, zirconium and copper, and the metal nitride includes any one selected from the group consisting of titanium nitride, tantalum nitride, tungsten nitride, aluminum nitride, hafnium nitride, zirconium nitride and copper nitride.

3. The method of claim 1, wherein the surface treatment includes an oxidation treatment.

4. The method of claim 3, wherein the oxidation treatment includes heat treatment or a plasma treatment using a material containing oxygen.

5. The method of claim 4, wherein the heat treatment is performed at a temperature of about 400° C. to about 550° C.

6. The method of claim 4, wherein the plasma treatment is performed at a temperature of about 250° C. to about 500° C. at a power source of about 100 watts to about 500 watts.

7. The method of claim 1, wherein the surface treatment includes a reduction treatment.

8. The method of claim 7, wherein the reduction treatment includes a heat treatment or a plasma treatment using hydrogen (H₂) gas, ammonia (NH₃) gas, a mixture of hydrogen (H₂) and nitrogen (N₂), a mixture of ammonia (NH₃) and nitrogen (N₂) and a mixture of hydrogen (H₂) and ammonia (NH₃).

9. The method of claim 8, wherein the heat treatment is performed at a temperature of about 300° C. to about 800° C.

10. The method of claim 8, wherein the plasma treatment is performed at a temperature of about 20° C. to about 800° C. at a power source of about 400 watts to about 2500 watts.

11. The method of claim 1, wherein the precursor includes any one selected from the group consisting of an amide group, an alkoxide group and a halide group.

12. The method of claim 1, further comprising forming the second thin layer on the first thin layer on which the binding inhibitor is formed using the precursor.

13. The method of claim 12, wherein the second thin layer includes a metal oxide.

14. The method of claim 13, wherein the metal oxide includes at least one selected from the group consisting of HfO₂, ZrO₂, Ta₂O₅, Y₂O₃, Nb₂O₅, Al₂O₃, TiO₂, CeO₂, In₂O₃, RuO₂, MgO, SrO, B₂O₃, SiO₂, GeO₂, SnO₂, PbO, PbO₂, Pb₃O₄, V₂O₃, La₂O₃, As₂O₅, As₂O₃, Pr₂O₃, Sb₂O₃, Sb₂O₅, CaO, P₂O₅ and combinations thereof.

15. The method of claim 12, wherein the second thin layer is formed by a chemical vapor deposition (CVD) process or an atomic layer deposition (ALD) process.

16. The method of claim 1, wherein the first thin layer is a floating gate, the binding inhibitor is part of a dielectric layer, and the second thin layer is a control gate of a flash memory device.

17. The method of claim 16, wherein the dielectric layer comprises a metal oxide.

18. The method of claim 17, wherein the metal oxide includes any one selected from the group consisting of HfO₂, ZrO₂, Ta₂O₅, Y₂O₃, Nb₂O₅, Al₂O₃, TiO₂, CeO₂, In₂O₃, RuO₂, MgO, SrO, B₂O₃, SiO₂, GeO₂, SnO₂, PbO, PbO₂, Pb₃O₄, V₂O₃, La₂O₃, As₂O₅, As₂O₃, Pr₂O₃, Sb₂O₃, Sb₂O₅, CaO, P₂O₅ and combinations thereof.

19. The method of claim 16, wherein the dielectric layer is formed by:
providing the precursor onto the floating gate;
chemisorbing the first element of the precursor onto the floating gate and physisorbing the second element of the precursor onto the floating gate;
removing the second element from the floating gate by providing a first purge gas onto the floating gate;
providing an oxidizing agent onto the floating gate;
reacting the first element with the oxidizing agent, thereby forming the binding inhibitor containing the first element of the precursor and the oxidizing agent; and
removing a residual oxidizing agent that is not reacted with the first element from the floating gate by providing a second purge gas onto the floating gate on which the binding inhibitor is formed.

20. The method of claim 19, further comprising repeating the operations of providing the precursor through removing the residual oxidizing agent sequentially at least once.

21. The method of claim 16, wherein the dielectric layer is formed by:
providing the precursor onto the floating gate;
reacting an oxidizing agent with the precursor, thereby forming a combination of the oxidizing agent and precursor; and
depositing the combination of the oxidizing agent and precursor onto the floating gate.

22. The method of claim 1, wherein the first thin layer is a lower electrode, the binding inhibitor is part of a dielectric layer, and the second thin layer is an upper electrode of a capacitor.

23. The method of claim 22, wherein the lower electrode includes a cylindrical type or a stacked type.
